(19) United States
(12) Patent Application Publication
(10) Pub. No.: US 2009/0014802 A1
(43) Pub. Date: Jan. 15, 2009

(54) Semiconductor device and method for manufacturing the same

(75) Inventor: Keizo Kawakita, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/216,903

(22) Filed: Jul. 11, 2008

(30) Foreign Application Priority Data
Jul. 13, 2007 (JP) 2007-184549

(51) Int. Cl. H01L 29/78; H01L 21/336

(52) U.S. Cl. 257/365; 438/283; 257/E29.264; 257/E21.421

(57) ABSTRACT

The semiconductor device according to the present invention is a Fin-FET that can substantially increase the channel width without unnecessarily elevating the height of the Fin. The Fin-FET has gate electrodes 22 formed on the upper surface, both left and right sides and the bottom surface of channel-forming semiconductor layer 11a formed by processing semiconductor substrate 11 into a fin shape; and a channel region the four surfaces of which are surrounded by gate electrodes 22.

This application is based upon and claims the benefit of priority from Japanese patent application No. 2007-1784549, filed on Jul. 13, 2007, the disclosure of which is incorporated herein in its entirety by reference.

### BACKGROUND OF THE INVENTION

1. Field of the Invention

The present invention relates to a semiconductor device and a method for manufacturing the same, and more specifically, to a novel structure of a Fin-structure field effect transistor (hereafter referred to as “Fin-FET”), and a method for manufacturing the same.

2. Related Art

With the advance of the miniaturization of semiconductor elements, the impurity concentration in a channel region has been increased to prevent the punch through phenomena in transistors. However, in the case of select transistors used in a DRAM (dynamic random access memory) cell array, the increased impurity concentration causes a stronger electric field in the vicinity of the source-drain junction and, in turn, increases a junction leakage current, which causes an adverse effect of deteriorating refresh properties. A conventional planar-type MOS transistor has only one surface under the gate as a channel surface that is conductive to Iₒₙ. In order to increase Iₒₙ, the gate has to be widened, which in turn increases the layout area of the transistor. This imposes a problem of the rise in chip costs.

As a countermeasure, a technique known as RCAT (recess-channel-array transistor) in which the impurity concentration in the channel region is lowered and in which refresh properties are improved by digging down the substrate to increase in length of the gate width (L_{gate}) has been developed. However, this technique also has problems of reduction of an ON-current (Iₒₙ) and increase in word line capacitance due to increase in channel resistance, and the difficulty of applying the technique is anticipated when miniaturization further advances.

Therefore, in order to solve the problem of reduction of Iₒₙ and the problem of increase in word line capacitance, the development of transistors for a cell array having a Fin structure is under way. A Fin-transistor has a double gate structure, and has better gate controllability than a planar-type transistor. Also by narrowing the gate width (W) less than the twice the width of a depletion layer, the channel region can be almost completely depleted, and preferable OFF-current (I_{off}) can be obtained. Therefore, the Fin-transistor is hopeful for a completely depleted transistor being excellent in sub-threshold characteristics.

In conventional Fin-transistors, there are known methods as shown in FIG. 33 including a method for forming a Fin-transistor wherein gate electrode 102a is conformally crosswise overlaid on semiconductor layer 101 of a Fin structure formed on a substrate (FIG. 33 (a)); a method for forming a Fin-transistor wherein gate electrode material 102b is formally buried between semiconductor layers 101 of a Fin structure (FIG. 33 (b)); and a method for forming a Fin-transistor wherein slits are formed on the sides of semiconductor layer 101 of a Fin structure, and the slits are buried to form gate electrode material 102c on an insulation film (not shown) (FIG. 33(c)) are known. In FIG. 33, a gate insulation film, an element isolating insulation film and the like are omitted. In FIGS. 33 (a) and (b), since the gate electrode is in contact with the substrate, an expensive substrate, such as SOI (silicon on insulator), is required. Alternatively, a method wherein an element isolating film is buried between semiconductor layers of a Fin structure to intend insulation from the substrate has also been known. On the other-hand, in the example shown in FIG. 33 (c), since the gate electrode is not in direct contact with the substrate, the Fin-transistor can be formed using an ordinary substrate. Although the gate structure is shown formed on the outside of the semiconductor layer in FIG. 33 (c), a method wherein a recess is formed in the semiconductor layer to form the gate structure is also been known as disclosed in Japanese Patent Application Laid-Open No. 2007-27678.

On the other hand, although the cell transistor generally shares the contact on the bit-line sides of two cell transistors, a 1-transistor DRAM (referred to as “1TRDRAM”) is disclosed in, for example, IEEE, TRANSACTIONS ON ELECTRON DEVICES. Vol. 52, No. 10, October 2005. pp. 2220-2226. Here, an SOI substrate is used to form the 1TRDRAM.

When the cell area of the DRAM is reduced, ordinary planar-type transistors suffer from a problem that the width of transistor determinative of the current driving ability is reduced, and therefore, the current driving ability is degraded as the cell area is reduced. To solve these problems, a Fin-FET is used. In a conventional Fin-FET, either two surfaces on both sides of the semiconductor layer sandwiched between gate electrodes or three surfaces including an upper surface added to the two surfaces form a channel region, and therefore, the height of the fin should be elevated to further widen the channel, but has a limitation.

Heretofore, an expensive SOI substrate has been required to form a 1TRDRAM, and the reduction of manufacturing costs has been demanded.

### SUMMARY OF THE INVENTION

Therefore, an object of the present invention is to provide a Fin-FET structure and a method for manufacturing the same in which the practical channel width can be increased without unnecessarily elevating the height of the fin.

Another object of the present invention is to realize a 1TRDRAM without using an expensive SOI substrate.

To solve such problems, the present invention provides a novel semiconductor device having a Fin-structure field effect transistor (Fin-FET).

The Fin-FET of the present invention includes a channel region surrounded by a gate electrode formed on the upper surface, both left and right sides and the bottom surface of a channel-forming semiconductor layer formed by shaping a semiconductor substrate into a fin.

The present invention also relates to a method for manufacturing a semiconductor device having a Fin-FET, including:
(A) etching a semiconductor substrate to form a fin-shaped channel-forming semiconductor layer, and forming trenches for isolating the channel-forming semiconductor layer;
(B) forming an element isolating insulation film in the trenches for isolating the channel-forming semiconductor layer;
(C) forming two slit portions facing each other in the channel-forming semiconductor layer;
(D) forming insulation films on an upper surface of the channel-forming semiconductor layer and in the slit portions;
(E) removing the insulation films on the bottom surfaces of the slit portions;
(F) isotropically etching the semiconductor layers exposed on the bottom surfaces of the slit portions to form cavity portions under the slit portions;
(G) removing at least the remaining insulation films in slit portions, and thereafter forming a gate insulation film on the entire surface of exposed semiconductor layers; and
(H) filling the slit portions and the cavity portions with a gate electrode material and forming a film over the entire surface and processing the film into the shape of a gate electrode.

According to the present invention, a gate electrode is also formed under the lower surface area of fins by performing Si isotropic etching at a bottom surface of slit using an oxide film as a mask so as to make the area function as a channel region. This increases in a substantial channel width and thereby enables to form a transistor with improved Iₒₙ.

Also by stacking and disposing n channel regions (n is an integer of at least 2) surrounded by gate electrodes (BOX structure), a transistor with n-times Iₒₙ can be formed.

Furthermore, by trapping carriers such as hot carrier in the formed BOX structure, a 1-transistor DRAM using a change in threshold voltage caused by changing a practical substrate bias can be realized.

### BRIEF DESCRIPTION OF THE DRAWINGS

FIG. 1 is planer layout diagram of a Fin-FET according to an exemplary embodiment of the present invention.

FIGS. 2 to 17 are process sectional views for illustrating a method for manufacturing a Fin-FET according to an exemplary embodiment of the present invention.

FIG. 18 is a layout diagram of a memory cell array using Fin-FETs according to the present invention.

FIG. 19 is a conceptual diagram for illustrating the operational state of a Fin-FET according to the present invention.

FIGS. 20 to 32 are process sectional views for illustrating a method for manufacturing a Fin-FET according to another exemplary embodiment of the present invention.

FIGS. 33(a) to 33(c) are schematic perspective views showing the structures of conventional Fin-FETs.

### DETAILED DESCRIPTION OF THE PREFERRED EMBODIMENTS

In Fin-FET according to the related art, the upper surface and both sides of a channel are surrounded by gate electrodes, while in the present invention, by forming a channel region whose upper surface, both side surfaces and the bottom surface is surrounded by gate electrodes. In the present invention, such a structure is obtainable by digging down a substrate silicon and further by isotropic etching below a slit portions formed on both sides of a channel semiconductor layer to provide a cavity portion to be the bottom surface of the channel region. That is, a polycrystalline silicon (hereinafter referred to as “polysilicon”) layer for a gate electrode is buried in the cavity portion and slit portions. As a result, the channel can be practically widened without unnecessarily elevating the height of the fin.

In order to manufacture such a structure, in the same manner as the conventional Fin-FET manufacturing, a substrate silicon is first etched to form a fin-shaped channel-forming semiconductor layer (hereafter referred to as “Fin”), and an element isolating insulation film is formed to isolate respective fins.

Next, two slit portions facing each other are formed in the formed Fin. Although depending on the width of the Fin, the slit portions are preferably formed in the vicinity of both sides of the Fin, specifically, in the boundary with the element isolating film that defines the Fin. The slit portions, for example, are formed by utilizing the step between the element isolating film and the upper surface of the Fin. First, a silicon nitride film is conformally formed on the step and then a silicon oxide film is laminated on the silicon nitride film. The silicon oxide film is etched back by using the silicon nitride film as an etching stopper to bury the silicon oxide film in the step. Next, a resist pattern that has an opening equivalent to the length of the slit is formed on the substrate, and the silicon nitride film is selectively patterned in the opening to form a slit opening of a width equivalent to the thickness of the silicon nitride film. Thereafter, by anisotropic etching of the silicon layer of the Fin using the element isolating film and the silicon oxide film on the silicon nitride film as masks, the slit portions can be formed. As described, the width of the slit portions can be controlled by adjusting the height of the step and the thickness of the silicon nitride film. The depth of the slit portions may be optionally determined corresponding to the distance between the slits and the shape of the slits so that the channel-forming semiconductor layer of a sufficient thickness remains on the upper portion of the cavity portion.

On the surface of exposed silicon in the slit portions thus formed, an insulation film such as a silicon oxide film is formed by thermal oxidation. Then, the insulation film of the bottom of the slit portions is removed by anisotropic dry etching or the like to expose substrate silicon on the bottom of the slit portions.

Next, the substrate silicon exposed through the slit portions is undergone isotropic etching, such as chemical dry etching (CDE) using an etchant gas to form a cavity portion under the slits. By isotropic etching from the two slit portions facing each other, two cavity portions are formed, and by continuing etching, the two cavity portions are connected. In the present invention, although the channel can be widened even if the two cavity portions are not connected, it is preferable that the two cavity portions are formed so as to be connected. The lower surface of the channel semiconductor layer formed by cavity portions that have such isotropically etched surface is longer than the upper surface, and the channel can be significantly widened.

Thereafter, the insulation film formed in the slit portions, the insulation film for the hard mask and the like are removed and then a gate insulation film is formed on the silicon layer of the exposed Fin. Subsequently, a gate electrode material, such as polysilicon, is buried in the cavity portions and slit portions by a CVD method or the like to form a film on the entire surface, and formed into a gate electrode shape. The gate electrode may be of a poly-metal structure wherein a metal film is formed on a polysilicon layer.

Finally, source and drain regions are formed in the same manner as in an ordinary MOSFET to obtain a Fin-FET according to the present invention.

Second slit portions can be formed on the bottom surface of the cavity portions formed as described above, a second cavity portion can be further formed under the second slit portions to form two stages of channel-forming semiconductor layers surrounded by gate electrodes,(channel region). The process can be further repeated to form multiple stages of channel regions. Although desired number of stages can be obtained depending on the purpose, since the height of the Fin should be elevated to increase the number of stages, it is preferable to limit the number of the stages to a minimum necessary number. It is needless to say that the number of stages naturally has a limit for various reasons, such as the coverage characteristics of the gate electrode material. However, it is not always true if such reasons are cleared in the future.

The present invention will be specifically described below referring to exemplary embodiments; however, the present invention is not limited to these exemplary embodiments, but various changes may be made without departing from the scope of the invention.

### EXAMPLE 1

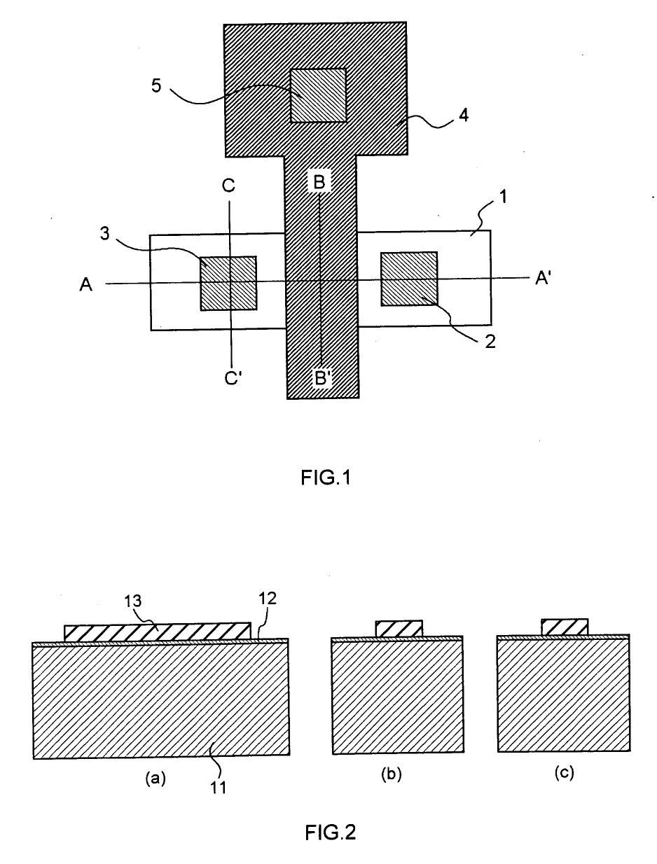

The first exemplary embodiment of the present invention will be described referring to FIGS. 1 to 17.

FIG. 1 is an upper surface layout diagram of a Fin-FET according to the present invention. In FIG. 1, reference numeral 1 denotes an active layer, 2 denotes a contact for a source, 3 denotes a contact for a drain, 4 denotes a gate electrode, and 5 denotes a contact for a gate electrode. In each of FIGS. 2 to 32, sub-figures (a), (b) and (c) show cross-sectional structure diagrams along the A-A′ line, B-B′ line and C-C′ line in FIG. 1, respectively.

First, silicon oxide film 12 of a thickness of 13 nm is formed on substrate silicon 11 by thermal oxidation. Thereafter, silicon nitride film 13 is formed, and processed by conventional photolithography using a resist film (not shown) patterned into the shape of the active layer region as a mask (FIG. 2).

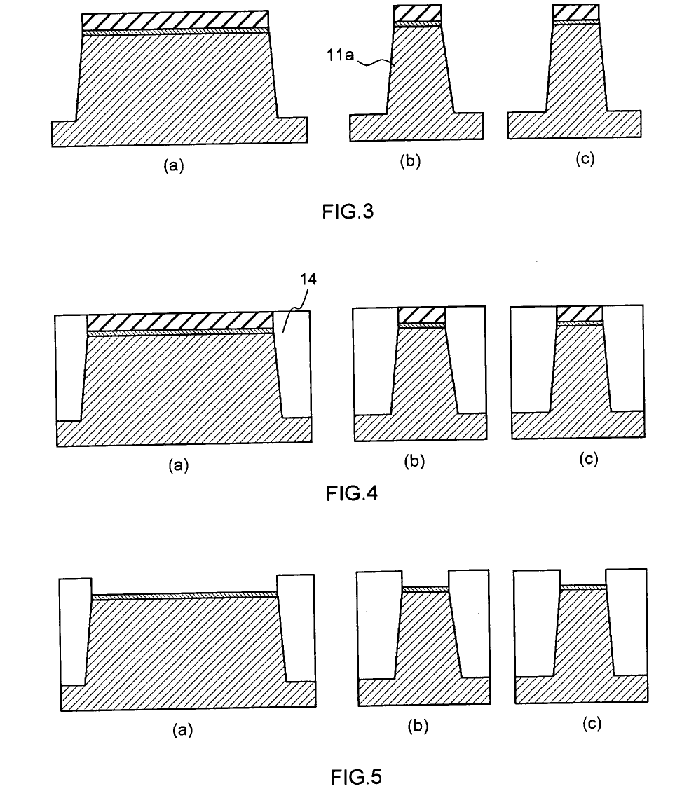

Next, silicon oxide film 12 and substrate silicon 11 are etched back to a depth of 200 nm by anisotropic dry etching using processed silicon nitride film 13 as a mask to form a channel-forming semiconductor layer (Fin) 11a (FIG. 3). Then, an HDP (high density plasma) oxide film of a thickness of 350 nm is deposited, and the oxide film on silicon nitride film 13 is removed by CMP (chemical mechanical polishing) to form element isolating insulation film 14 as shown in FIG. 4.

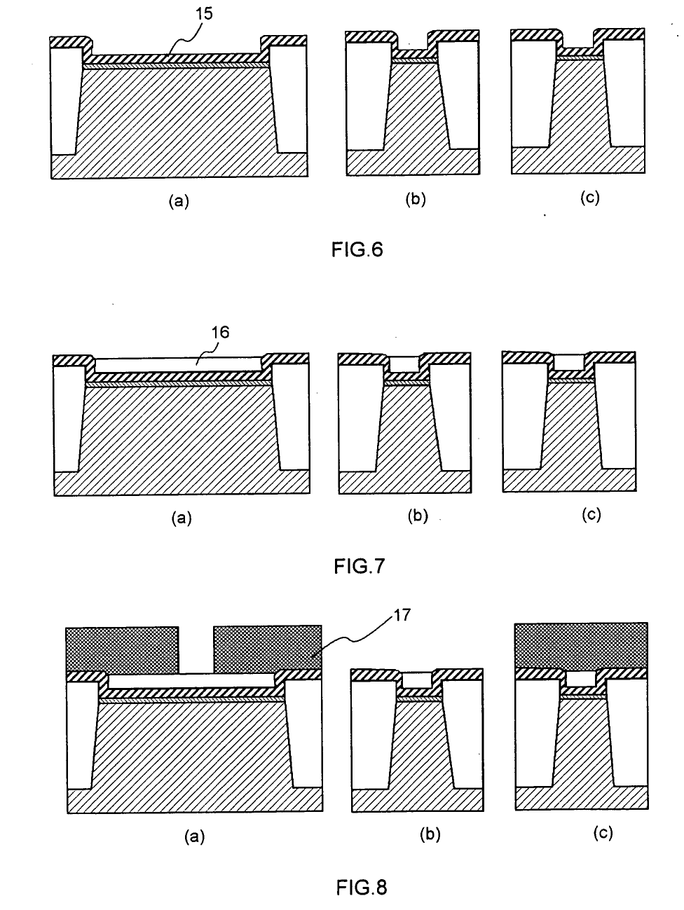

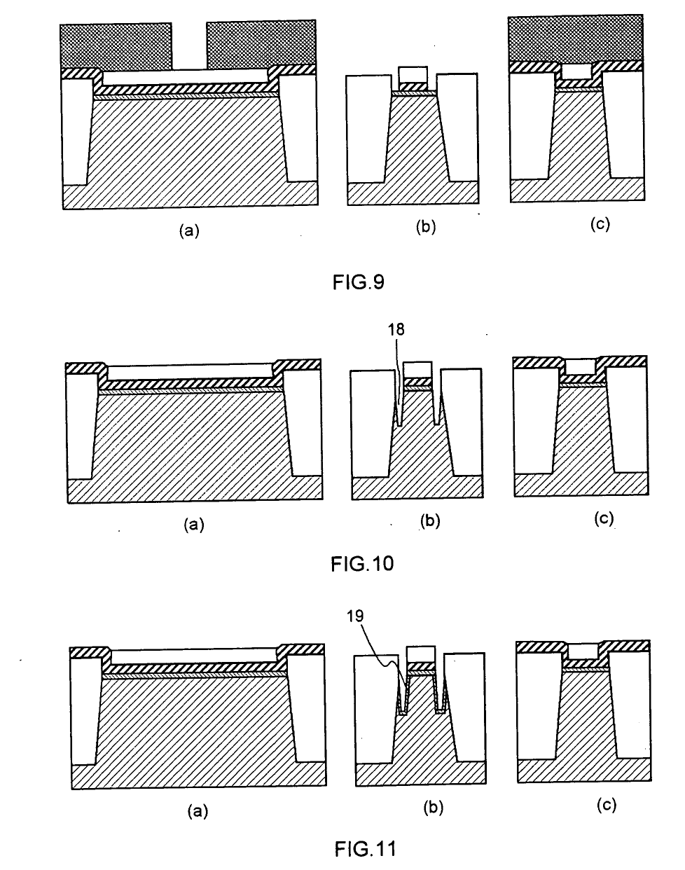

Next, silicon nitride film 13 was removed using hot phosphoric acid (FIG. 5). Then, silicon nitride film 15 of a thickness of 15 nm was deposited (FIG. 6), silicon oxide film 16 of a thickness of 20 nm was deposited thereon, and planarized by CMP using silicon nitride film 15 as a stopper film (FIG. 7) Next, resist pattern 17 having an opening for the channel forming region is formed using conventional lithography (FIG. 8). Silicon nitride film 15 was anisotropically etched by dry etching using resist pattern 17 and silicon oxide film 16 as masks (FIG. 9).

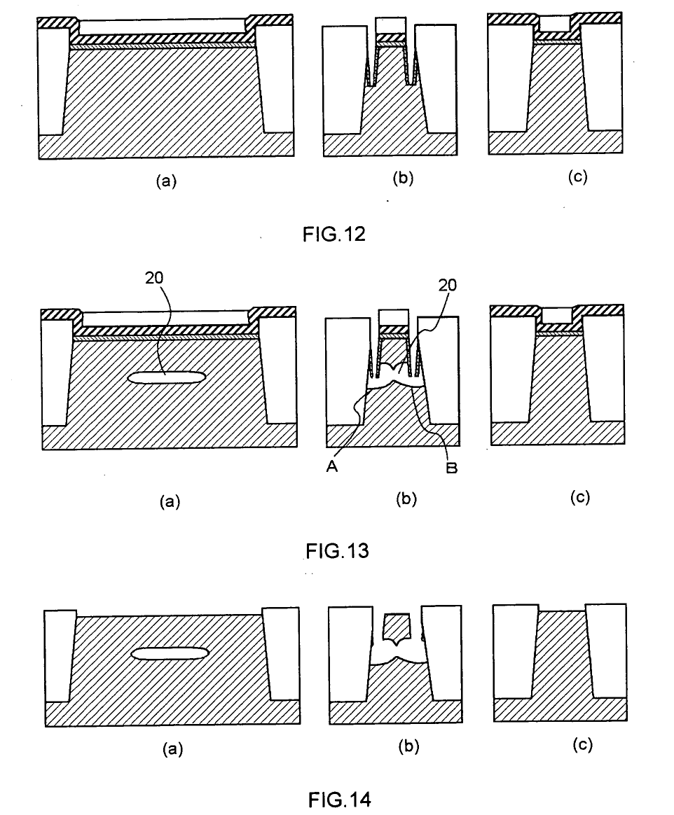

Next, the resist was removed, and substrate silicon 11 was anisotropically etched by dry etching using silicon oxide film 16 and silicon nitride film 15 as masks to form slit portions 18 as shown in FIG. 10. Then, silicon oxide film 19 of a thickness of 5 nm is grown in the exposed slits (FIG. 11).

Next, silicon oxide film 19 on the bottoms of slit portions were etched by anisotropic dry etching to expose the silicon layer of Fin 11a on the bottom surfaces of the slit portions (FIG. 12). Then, Fin 11a is etched by Si isotropic etching (CDE: chemical dry etching) mainly using NF₃ etching gas to form cavity portion 20. At this time, an isotropically etched surface A formed from a slit portion is preferably in contact with an isotropically etched surface B formed from the other slit portion to form a structure with connected cavity portion 20 (FIG. 13). Next, at least 5 nm of the silicon oxide film was removed by wet etching using HF, and silicon nitride film 15 and silicon oxide film 12 as stopper films were also removed (FIG. 14). Next, gate insulation film 21 of a thickness of 6 nm, a polysilicon film for gate 22 of a thickness of 80 nm, metal film 23 formed by laminating a tungsten nitride (WN) film of a thickness of 5 nm and a tungsten (W) film of a thickness of 45 nm, and cap silicon nitride film 24 of a thickness of 140 nm, were sequentially deposited (FIG. 15). Thereafter, a conventional process for manufacturing a MOS transistor is carried out.

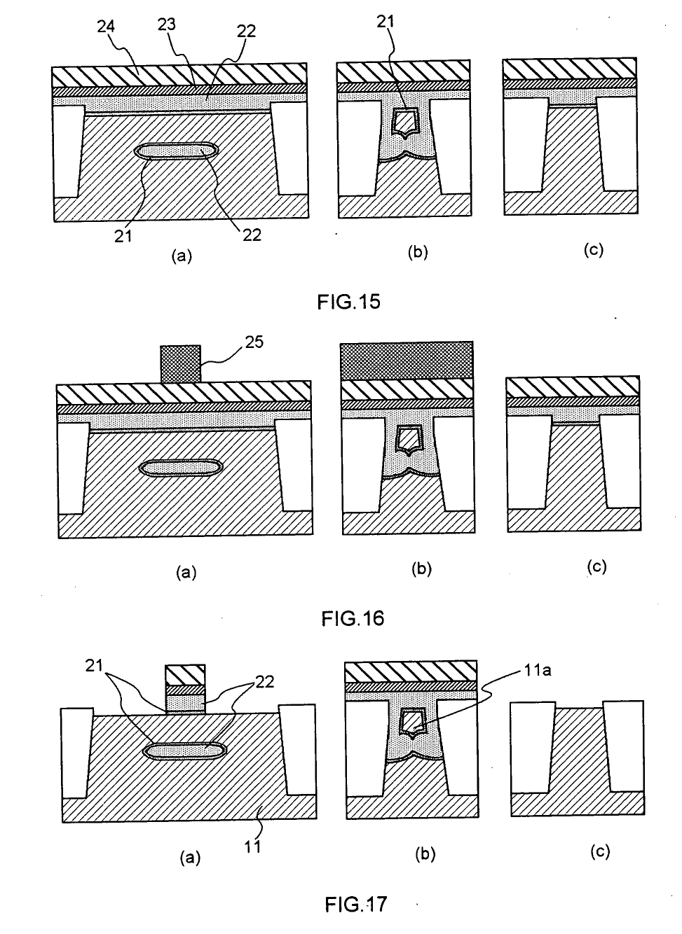

Specifically, resist pattern 25 was formed on cap silicon nitride film 24 using conventional lithography (FIG. 16), and a laminate structure sequentially laminated in the process shown in FIG. 15 was formed in the shapes of gate electrodes (FIG. 17).

Thereafter, source and drain diffused layer is formed by a conventional process for manufacturing a MOS transistor.

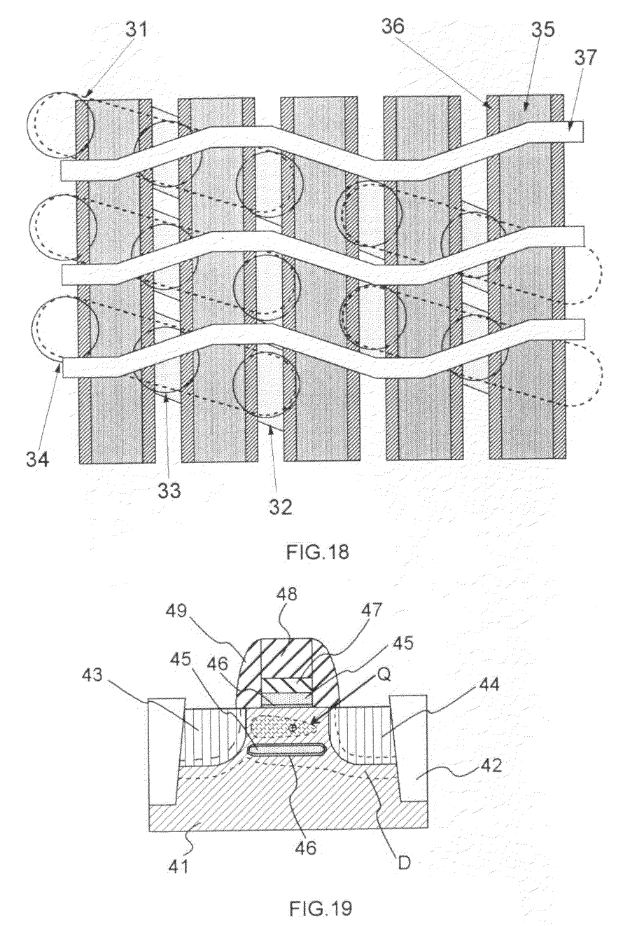

The cell layout when the present invention is applied to a 6 F² memory cell structure is shown in FIG. 18. By using the transistor of the present invention as a pass transistor of a DRAM, the channel can be widened without increasing the plane area. Thereby, since the current driving ability of the pass transistor is enhanced, the write and read time to and from the capacitor can be shortened, and a high-performance DRAM can be manufactured. In the cell layout shown in FIG. 18, two transistors are formed in each of field active regions 31 obliquely laid out (shown by dashed lines), contacts 33 to bit lines 37 are formed on the field active regions shared with the two transistors, and contacts 34 to the capacitor are formed on both sides. In this example, selectively formed epitaxial silicon 32 has been grown prior to forming a contact in order to reduce contact resistance. The reference numeral 35 denotes word lines that become gate electrodes, and the state wherein LDD sidewalls are formed on both sides is shown.

The operating state of the transistor manufactured in the first exemplary embodiment is shown in FIG. 19. The region surrounded by gate polysilicon 45 is isolated by a depletion layer D (region shown by dashed lines), and holes with energy generated in the vicinity of drain 44 are held in a carrier holding region Q, surrounded by the gate electrodes. Thereby, the threshold voltage of the transistor is lowered. By reading difference in the threshold voltage due to change in the practical substrate bias as a storage data, a 1-transistor DRAM can be realized. Thereby, the area of the DRAM cell can be reduced, the area of the DRAM chip is shrunk, and the manufacturing costs can be lowered. In FIG. 19, other reference numerals are, 41: substrate silicon, 42: element isolating insulation film, 43: source, 46: gate insulation film, 47: gate metal film, 48: cap silicon nitride film, and 49: LDD sidewall of a silicon nitride film.

### EXAMPLE 2

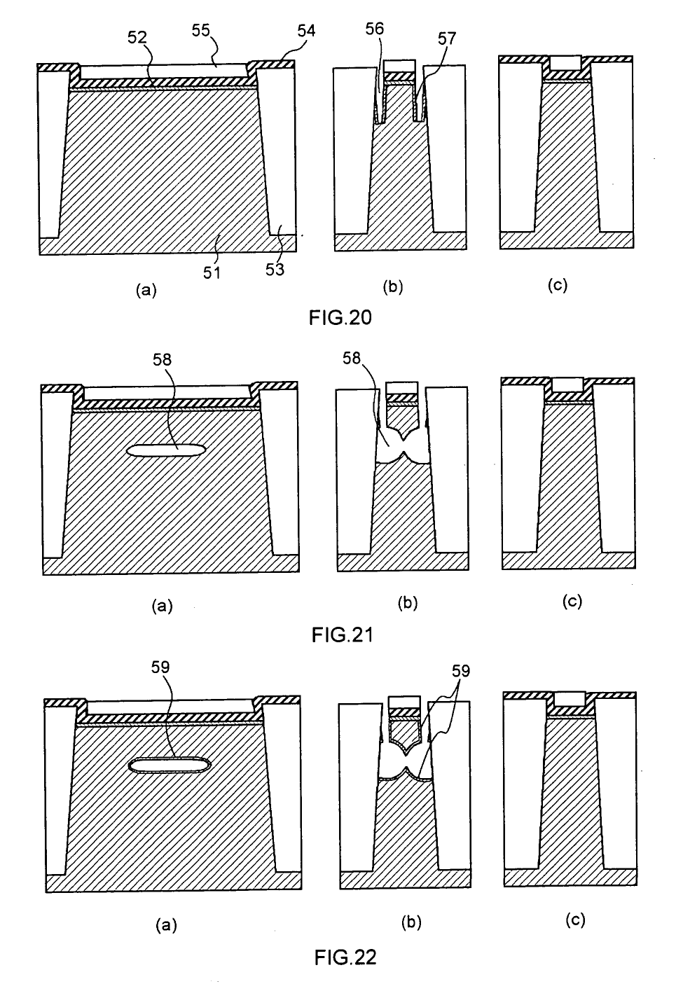

Next, a method for manufacturing a semiconductor device according to the second exemplary embodiment of the present invention will be described referring to FIGS. 20 to 32. The manufacturing steps from FIG. 2 to FIG. 11 are identical to the steps described above except that the substrate etched for isolating the elements is 400 nm.

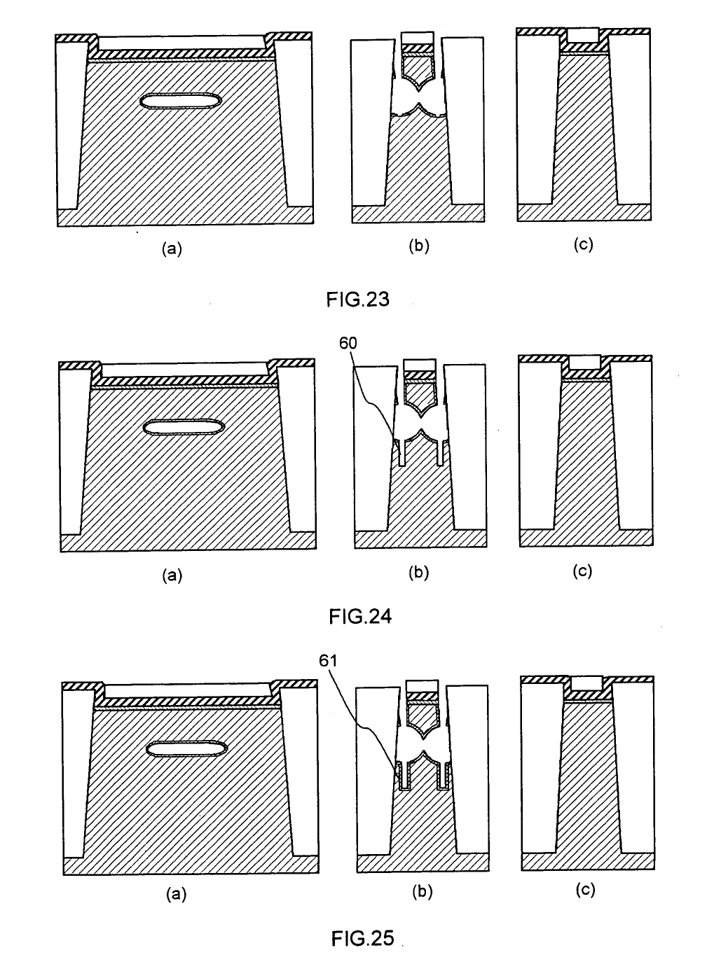

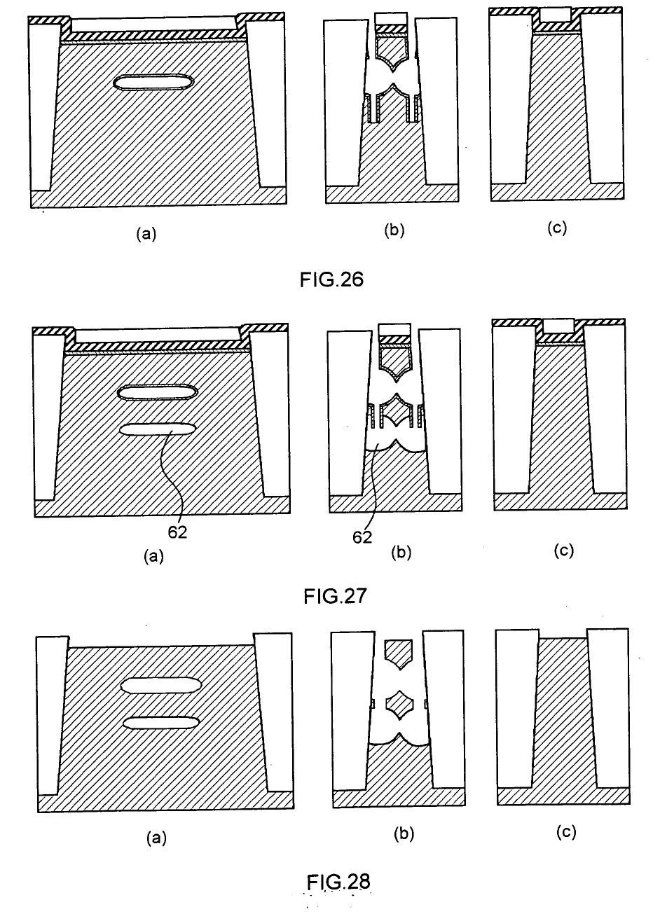

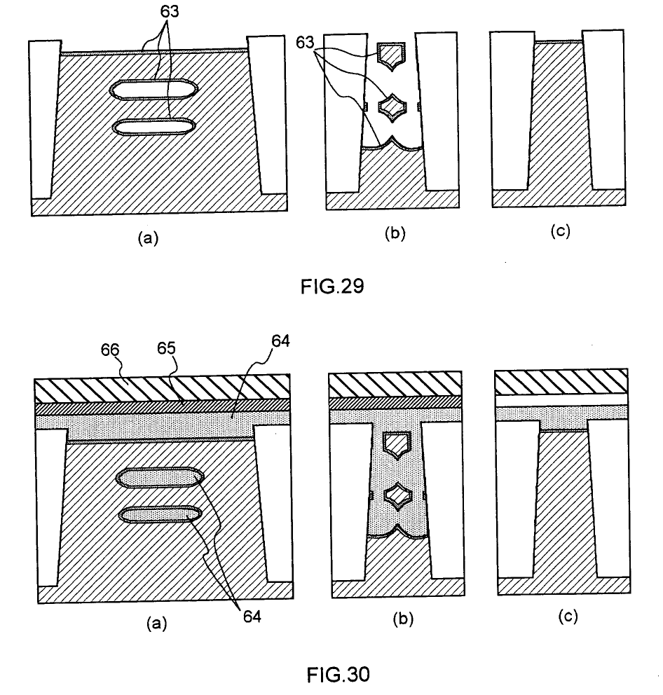

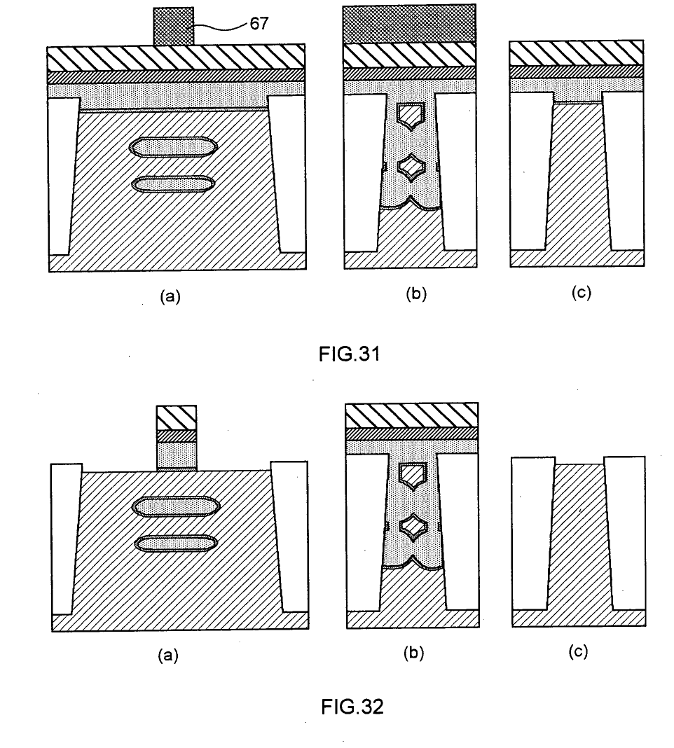

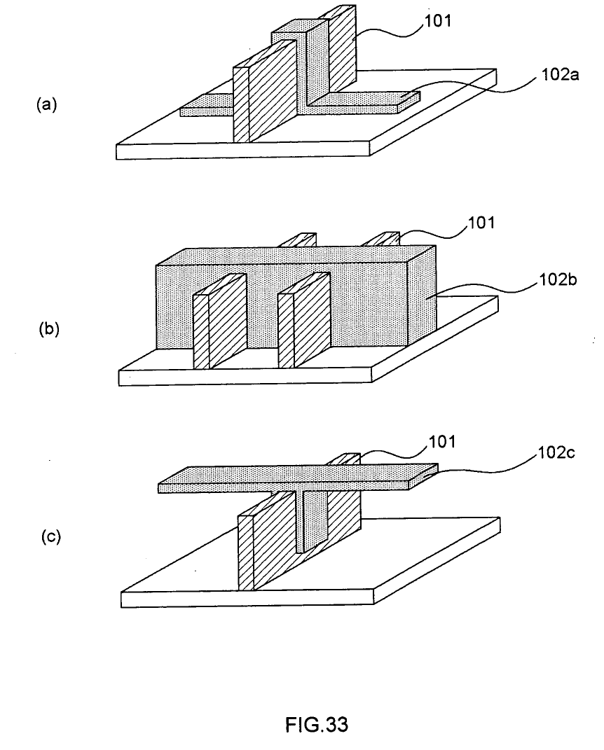

In the same manner as described above, silicon oxide films 57 of a thickness of 5 nm is grown in slits 56, and then silicon oxide films 57 on the bottoms of the slits are removed by anisotropic dry etching to expose substrate silicon 51 (FIG. 20). Next, in the same manner as described in the first exemplary embodiment, substrate silicon 51 is etched by Si isotropic etching mainly using NF₃ etching gas to form first cavity 58, and then at least 5 nm of the oxide film is removed by wet etching using HF (FIG. 21). Next, silicon oxide films 59 of a thickness of 5 nm are grown on the exposed silicon in slits 56 and first cavity 58 (FIG. 22). Next, silicon oxide films 59 are etched through slits 56 to expose substrate silicon 51 on the bottom of the cavity (FIG. 23). Then, substrate silicon 51 is etched by anisotropic etching to form second slits 60 (FIG. 24). Silicon oxide film 61 of a thickness of 5 nm is grown on substrate silicon 51 exposed in second slits 60 (FIG. 25). In the same manner as described above, silicon oxide film 61 is etched by anisotropic dry etching to expose substrate silicon 51 on the bottom of second slits 60 (FIG. 26). In the same manner as described above, substrate silicon 51 is etched using isotropic etching (CDE) to form second cavity 62 (FIG. 27). Next, silicon oxide film 55 is removed, and silicon nitride film 54 and silicon oxide films 52, 59 and 61 as stopper films are also removed (FIG. 28). Then, gate insulation films 63 are formed (FIG. 29), and polysilicon film 64 of a thickness of 80 nm for the gate, metal film 65 composed of the lamination of WN that has a thickness of 5 nm and W that has a thickness of 45 nm, and cap silicon nitride film 66 of a thickness of 140 nm, are sequentially deposited (FIG. 30). Next, resist pattern 67 is formed on the gate forming region using conventional lithography (FIG. 31). Next, cap silicon nitride film 66 is etched using resist pattern 67 as a mask, and after the resist is removed, metal film 65, polysilicon film 64 for the gate, and gate insulation film 63 are undergone dry etching to form the gate electrode. Thereafter, the source and drain diffusion layer are formed by the conventional MOS transistor manufacturing process.

Thereby, a Fin-FET wherein two stages of channel regions of a BOX structure surrounded by gate polysilicon films 64 are stocked is formed.

Furthermore, repeating manufacturing processes shown in FIGS. 23 to 28 more than once, a structure wherein further multi-stage BOX structure is stacked can be realized.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A semiconductor device comprising a Fin-structure field effect transistor (Fin-FET),
wherein the Fin-FET comprises a channel region surrounded by a gate electrode formed on the upper surface, both left and right sides and the bottom surface of a channel-forming semiconductor layer formed by shaping a semiconductor substrate into a fin.

2. The semiconductor device according to claim 1,
wherein at least two stages of the channel region surrounded by the gate electrode are stacked.

3. The semiconductor device according to claim 1,
wherein the bottom surface of the channel region surrounded by the gate electrode has a surface undergone isotropic etching.

4. The semiconductor device according to claim 1,
wherein the Fin-FET is the pass transistor of DRAM.

5. The semiconductor device according to claim 1,
wherein the semiconductor device is a 1-transistor DRAM that carriers are trapped within the channel region surrounded by the gate electrodes, and storage data is readable as difference in threshold voltage caused by changing practical substrate bias.

6. A method for manufacturing a semiconductor device having a fin-structure field effect transistor (Fin-FET), comprising
(A) etching a semiconductor substrate to form a fin-shaped channel-forming semiconductor layer, and forming trenches for isolating the channel-forming semiconductor layer;
(B) forming an element isolating insulation film in the trenches for isolating the channel-forming semiconductor layer;
(C) forming two slit portions facing each other in the channel-forming semiconductor layer;
(D) forming insulation films on an upper surface of the channel-forming semiconductor layer and in the slit portions;
(E) removing the insulation films on the bottom surfaces of the slit portions;
(F) isotropically etching the semiconductor layers exposed on the bottom surfaces of the slit portions to form cavity portions under the slit portions;
(G) removing at least the remaining insulation films in slit portions, and thereafter forming a gate insulation film on the entire surface of exposed semiconductor layers; and
(H) filling the slit portions and the cavity portions with a gate electrode material and forming a film over the entire surface and processing the film into the shape of a gate electrode.

7. The method for manufacturing a semiconductor device according to claim 6 further comprising, after forming insulation films in the cavity portions formed in step (F), performing at least once: removing the insulation films in the cavity portions in the area projected through the slit portion, and thereafter forming a second slit portion using anisotropic etching under the cavity portions; forming an insulation film in the second slit portion, and thereafter removing the insulation film on the bottom of the second slit portion; and isotropically etching the semiconductor layer exposed on the bottom surface of the second slit portion to form a second cavity portion under the second slit portion.
